(19) United States
(12) Patent Application Publication
(10) Pub. No.: US 2015/0263212 A1
(43) Pub. Date: Sep. 17, 2015

(54) SUBSTRATE FOR SEMICONDUCTOR DEVICES, METHOD OF MANUFACTURING SUBSTRATE FOR SEMICONDUCTOR DEVICES, AND SOLID-STATE IMAGING DEVICE

(71) Applicant: Kabushiki Kaisha Toshiba, Minato-ku (JP)

(72) Inventors: Shinji UYA, Oita (JP); Nagataka Tanaka, Oita (JP); Mokuji Kageyama, Oita (JP); Hideo Numata, Ota (JP)

(73) Assignee: Kabushiki Kaisha Toshiba, Minato-ku (JP)

(21) Appl. No.: 14/635,303

(22) Filed: Mar. 2, 2015

(30) Foreign Application Priority Data
Mar. 13, 2014 (JP) 2014-050169

(51) Int. Cl. H01L 31/105; H01L 27/146; H01L 31/18

(52) U.S. Cl. CPC H01L 31/105; H01L 31/186; H01L 31/1804; H01L 27/14645

(57) ABSTRACT

According to one embodiment, a substrate for semiconductor devices includes a P-type semiconductor substrate, a P-type or N-type semiconductor layer, and a P-type or N-type epitaxial layer. The P-type or N-type semiconductor layer is provided at a surface layer of the semiconductor substrate and has a resistance value lower than a resistance value of the semiconductor substrate. The P-type or N-type epitaxial layer is provided on a surface of the semiconductor layer and has a resistance value higher than the resistance value of the semiconductor layer.

### CROSS-REFERENCE TO RELATED APPLICATIONS

This application is based upon and claims the benefit of priority from Japanese Patent Application No. 2014-050169, filed on Mar. 13, 2014; the entire contents of which are incorporated herein by reference.

### FIELD

Embodiments described herein relate generally to a substrate for semiconductor devices, a method of manufacturing a substrate for semiconductor devices, and a solid-state imaging device.

### BACKGROUND

Conventionally, when a solid-state imaging device is manufactured, there is a case where a P-type semiconductor substrate is used and a case where an N-type semiconductor substrate is used, which depend on the specification of the solid-state imaging device. Accordingly, if the specification of a solid-state imaging device is changed halfway, surplus semiconductor substrates will be wasted in some cases.

### BRIEF DESCRIPTION OF THE DRAWINGS

FIG. 1 is an explanatory view showing a schematic cross section of a substrate for semiconductor devices according to an embodiment;

FIGS. 2A to 2C are explanatory views respectively showing concrete examples 1 to 3 of the substrate for semiconductor devices according to the embodiment;

FIGS. 3A to 3D are schematic sectional views showing steps of manufacturing a substrate for semiconductor devices according to a first embodiment;

FIGS. 4A and 4B are schematic sectional views showing steps of manufacturing a substrate for semiconductor devices according to a modification of the first embodiment;

FIGS. 5A to 5D are schematic sectional views showing steps of manufacturing a solid-state imaging device of a front-side irradiation type according to the first embodiment;

FIGS. 6A to 6D are schematic sectional views showing steps of manufacturing a substrate for semiconductor devices according to a second embodiment;

FIGS. 7A and 7B are schematic sectional views showing steps of manufacturing a substrate for semiconductor devices according to a modification of the second embodiment;

FIGS. 8A to 8E are schematic sectional views showing steps of manufacturing a solid-state imaging device of a rear-side irradiation type according to the second embodiment; and

FIGS. 9A to 9D are schematic sectional views showing steps of manufacturing a substrate for semiconductor devices according to a third embodiment.

### DETAILED DESCRIPTION

In general, according to one embodiment, a substrate for semiconductor devices includes a P-type semiconductor substrate, a P-type or N-type semiconductor layer, and a P-type or N-type epitaxial layer. The P-type or N-type semiconductor layer is provided at a surface layer of the semiconductor substrate and has a resistance value lower than a resistance value of the semiconductor substrate. The P-type or N-type epitaxial layer is provided on a surface of the semiconductor layer and has a resistance value higher than the resistance value of the semiconductor layer.

Exemplary embodiments of a substrate for semiconductor devices, a method of manufacturing a substrate for semiconductor devices, and a solid-state imaging device will be explained below in detail with reference to the accompanying drawings. The present invention is not limited to the following embodiments. Further, the following explanation will be given of a case where a solid-state imaging device is taken as an example of the semiconductor devices, but the substrate for semiconductor devices according to each of the embodiments can be applied to any semiconductor device, such as a semiconductor logic circuit.

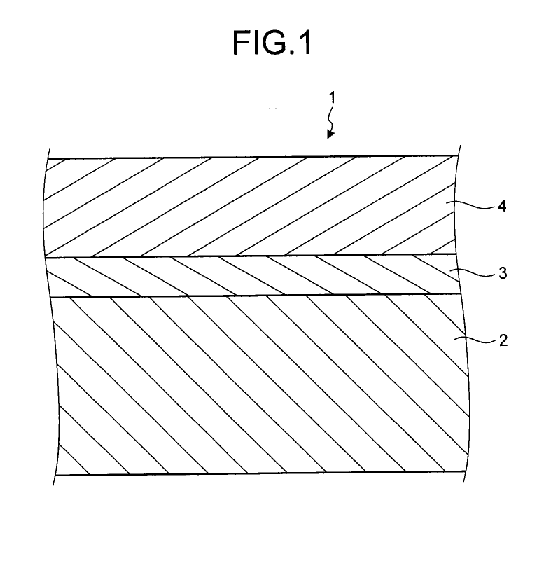

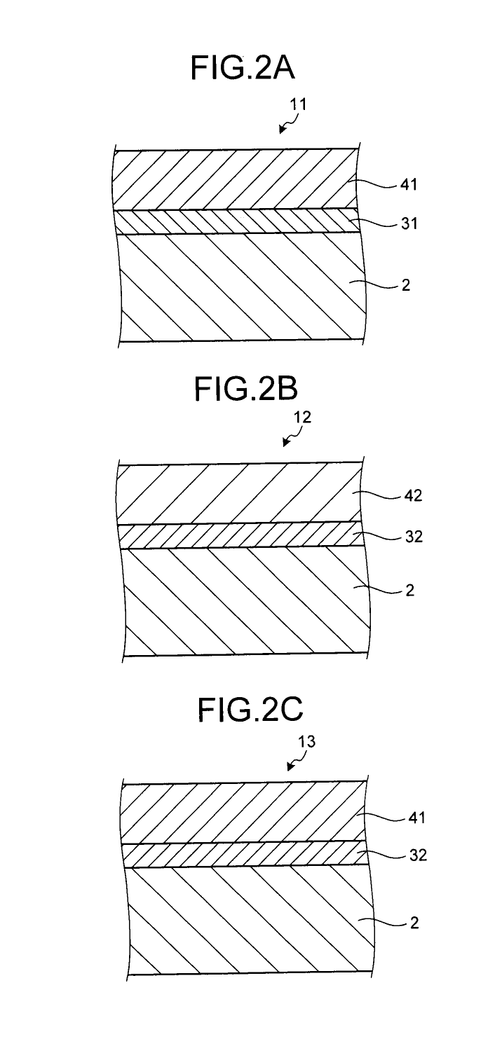

FIG. 1 is an explanatory view showing a schematic cross section of a substrate 1 for semiconductor devices according to an embodiment. FIGS. 2A to 2C are explanatory views respectively showing concrete examples 1 to 3 of the substrate 1 for semiconductor devices according to the embodiment. As shown in FIG. 1, the substrate 1 for semiconductor devices according to the embodiment includes a semiconductor substrate 2, a semiconductor layer 3, and an epitaxial layer 4.

For example, the semiconductor substrate 2 is a P-type Si (silicon) wafer doped with a P-type impurity, such as boron. The semiconductor layer 3 is a P-type or N-type Si layer provided at a surface layer of the semiconductor substrate 2 and having a resistance value lower than the resistance value of the semiconductor substrate 2. The epitaxial layer 4 is a Si layer provided on the surface of the semiconductor layer 3 and is formed by epitaxial growth of P-type or N-type Si having a resistance value higher than the resistance value of the semiconductor layer 3.

According to this substrate 1 for semiconductor devices, it is possible to manufacture solid-state imaging devices with various specifications, by using in common a P-type semiconductor substrate 2, which is less expensive than an N-type semiconductor substrate, and simply selecting the conductivity types of the semiconductor layer 3 and the epitaxial layer 4.

Specifically, as in a substrate 11 for semiconductor devices according to the concrete example 1 shown in FIG. 2A, an N-type low-resistivity semiconductor layer 31 is provided at a surface layer of the semiconductor substrate 2, and an N-type epitaxial layer 41 is provided on the surface of the N-type low-resistivity semiconductor layer 31. The N-type low-resistivity semiconductor layer 31 is formed to have a resistance value lower than that of the P-type semiconductor substrate 2. Further, the N-type epitaxial layer 41 is formed to have a resistance value higher than that of the N-type low-resistivity semiconductor layer 31. Adjustment of the resistance values is performed by adjusting the concentrations of an N-type impurity.

In the case of the substrate 11 for semiconductor devices, a photoelectric conversion element is formed in the epitaxial layer 41, and a positive voltage is applied to the N-type low-resistivity semiconductor layer 31; by which, for example, there may be manufactured a solid-state imaging device of a vertical overflow drain type that drains excessively photoelectric-converted electrons into the N-type low-resistivity semiconductor layer 31. Consequently, it is possible to manufacture a solid-state imaging device of a vertical overflow drain type, by use of the P-type semiconductor substrate 2, which is relatively inexpensive, without using an N-type semiconductor substrate, which is expensive.

Further, as in a substrate 12 for semiconductor devices according to the concrete example 2 shown in FIG. 2B, a P-type low-resistivity semiconductor layer 32 is provided at a surface layer of the P-type semiconductor substrate 2, and a P-type epitaxial layer 42 is provided on the surface of the P-type low-resistivity semiconductor layer 32.

The P-type low-resistivity semiconductor layer 32 is formed to have a resistance value lower than that of the semiconductor substrate 2. Further, the P-type epitaxial layer 42 is formed to have a resistance value higher than that of the P-type low-resistivity semiconductor layer 32. Adjustment of the resistance values is performed by adjusting the concentrations of a P-type impurity.

In the case of the substrate 12 for semiconductor devices, if a solid-state imaging device of a rear-side irradiation type is considered while its inter-pixel color mixing is given great importance, when a photoelectric conversion element is formed in the P-type epitaxial layer 42, the light-receiving surface of the photoelectric conversion element can be exposed by selective wet etching.

Specifically, in the steps of manufacturing a solid-state imaging device of a rear-side irradiation type, the rear side of the P-type epitaxial layer 42 can be exposed by selective wet etching that utilizes the difference in impurity concentration between the P-type low-resistivity semiconductor layer 32 and the P-type epitaxial layer 42.

Further, as in a substrate 13 for semiconductor devices according to the concrete example 3 shown in FIG. 2C, a P-type low-resistivity semiconductor layer 32 is provided at a surface layer of the P-type semiconductor substrate 2, and an N-type epitaxial layer 41 is provided on the surface of the P-type low-resistivity semiconductor layer 32.

The P-type low-resistivity semiconductor layer 32 is formed to have a resistance value lower than that of the semiconductor substrate 2. Further, the N-type epitaxial layer 41 is formed to have a resistance value higher than that of the P-type low-resistivity semiconductor layer 32. Adjustment of the resistance values is performed by adjusting the concentrations of P-type and N-type impurities.

In the case of the substrate 13 for semiconductor devices, when a photoelectric conversion element is formed in the N-type epitaxial layer 41, a certain thickness of the photoelectric conversion element can be obtained. Further, the P-type low-resistivity semiconductor layer 32 can be grounded such that it serves as ground.

As described above, in the case of the substrates 11, 12, and 13 for semiconductor devices according to the embodiment, it is possible to manufacture solid-state imaging devices with different specifications, by using in common a P-type semiconductor substrate 2. Consequently, even if the specification of a solid-state imaging device is changed, P-type semiconductor substrates 2 that have been used before the change of the specification can be used for manufacturing the solid-state imaging device after the change of the specification, and the generation of useless semiconductor substrates can thereby be reduced.

Further, if the same P-type semiconductor substrates 2 are continuously used for manufacturing solid-state imaging devices with various specifications, the cost of the substrates can be reduced.

Further, in a case where an N-type semiconductor substrate and a P-type semiconductor substrate 2 are respectively used in accordance with the specifications of solid-state imaging devices, it is necessary to develop techniques about gettering of contaminant metals for the respective types of the semiconductor substrates. On the other hand, in the case of the substrates 11, 12, and 13 for semiconductor devices according to the embodiment, they are unified in terms of using a P-type semiconductor substrate 2 as the semiconductor substrate, and thereby improve the efficiency of development of gettering techniques.

Next, a first embodiment concerning the concrete example 1, a second embodiment concerning the concrete example 2, and a third embodiment concerning the concrete example 3 will be explained below.

### First Embodiment

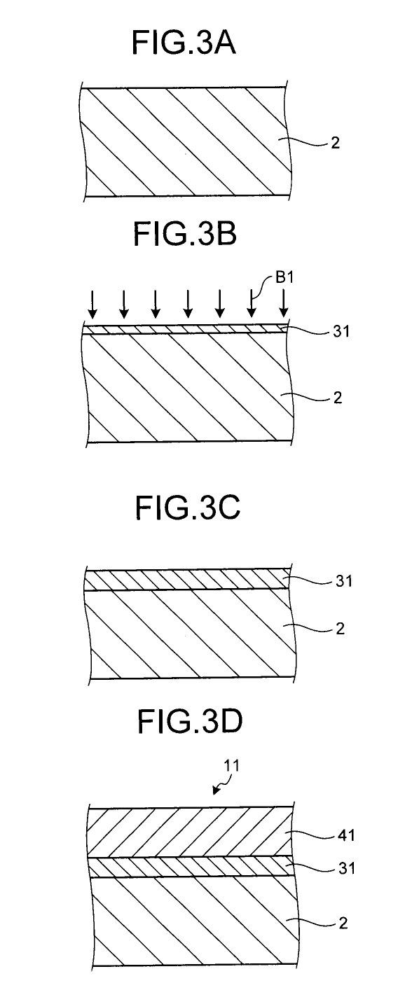

In the first embodiment, explanations will be given of the substrate 11 for semiconductor devices according to the concrete example 1 shown in FIG. 2A, in the order of a method of manufacturing the same, a modified method of manufacturing the same, and a method of manufacturing a solid-state imaging device of a front-side irradiation type using the substrate 11 for semiconductor devices. FIGS. 3A to 3D are schematic sectional views showing steps of manufacturing the substrate 11 for semiconductor devices according to the first embodiment.

When the substrate 11 for semiconductor devices is manufactured, as shown in FIG. 3A, a P-type semiconductor substrate 2 is prepared. For example, the P-type semiconductor substrate 2 is prepared by manufacturing an Si ingot while adding a P-type impurity, such as B (boron), to Si. For example, the B concentration in the ingot is set to be 1.0E15/cm³ to 1.0E16/cm³.

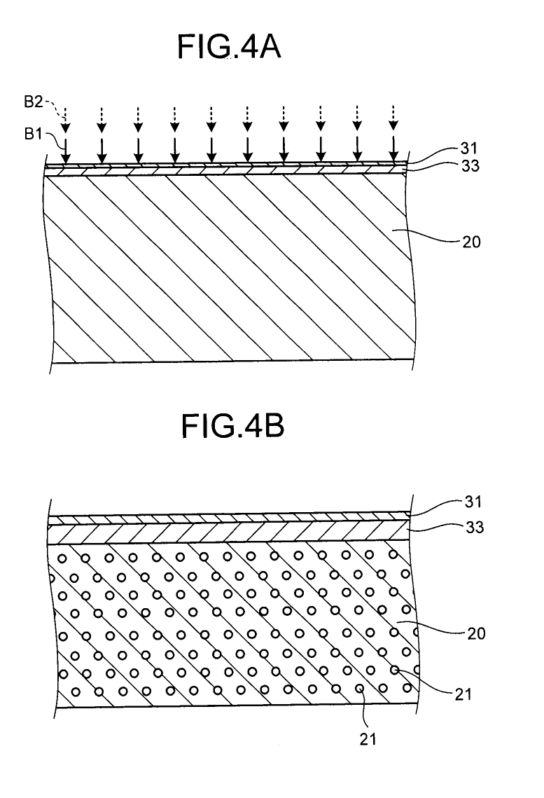

At this time, the oxygen concentration in the ingot is preferably set to be a predetermined concentration. In this respect, an explanation will be given later, with reference to FIGS. 4A and 4B. Then, the ingot thus manufactured is sliced into pieces with a predetermined thickness, and the P-type semiconductor substrate 2 is thereby manufactured. Consequently, the P-type semiconductor substrate 2 comes to have a resistance value of 1 Ωcm to 12 Ωcm.

This P-type semiconductor substrate 2 is subjected to high temperature annealing at 1100 to 1200° C. for 1 to 2 hours, so that a defect-free layer (not shown) called DZ (Denuded Zone) is formed at a surface layer, and an IG (intrinsic gettering) layer (not shown) having a BMD (Bulk Micro Defect) density of 1E9/cm³ or more is formed inside the P-type semiconductor substrate 2.

Subsequently, as shown in FIG. 3B, the surface of the P-type semiconductor substrate 2 is irradiated with an ion beam B1 containing N-type impurity ions, such as P (phosphorous), so that P ions are ion-implanted into a surface layer of the P-type semiconductor substrate 2, and an N-type low-resistivity semiconductor layer 31 is thereby formed.

Here, the P dose amount is set to be 1.0E13/cm² to 1.0E14/cm². Thereafter, an annealing process is performed to activate P ions in the N-type low-resistivity semiconductor layer 31. Consequently, as shown in FIG. 3C, the N-type low-resistivity semiconductor layer 31 increases its thickness, and comes to have a P concentration of about 3E16/cm³ to 3E17/cm³ at the highest concentration region and a resistance value of about 0.05 Ωcm to 0.2 Ωcm.

Subsequently, an N-type epitaxial layer 41 is formed on the surface of the N-type low-resistivity semiconductor layer 31, and the substrate 11 for semiconductor devices is thereby completed. For example, the N-type epitaxial layer 41 is formed by epitaxial growth of a Si layer doped with an N-type impurity, such as P, on the surface of the N-type semiconductor layer 31. The N-type epitaxial layer 41 is formed to have a desired P concentration within a range of 1.0E14/cm³ to 1.0E15/cm³.

Next, with reference to FIGS. 4A and 4B, an explanation will be given of a modified method of manufacturing the substrate 11 for semiconductor devices. FIGS. 4A and 4B are schematic sectional views showing steps of manufacturing a substrate for semiconductor devices according to a modification of the first embodiment.

As shown in FIG. 4A, in this modified manufacturing method, a P-type semiconductor substrate 20 containing oxygen at a predetermined concentration is prepared. For example, the oxygen concentration in the P-type semiconductor substrate 20 is set to be 12E17/cm³ to 18E17/cm³.

Then, the surface of the P-type semiconductor substrate 20 is sequentially irradiated with an ion beam B1 containing, e.g., C (carbon), and an ion beam B2 containing N-type impurity ions, such as P.

Here, the C dose amount is set to be 1.0E15/cm² to 2.0E16/cm², and the P dose amount is set to be 1.0E13/cm² to 1.0E14/cm². Consequently, a gettering site 33 containing ion-implanted C and an N-type low-resistivity semiconductor layer 31 containing ion-implanted P are provided in a sequentially stacked state at a surface layer of the P-type semiconductor substrate 20.

Thereafter, an annealing process is performed to activate P ions in the N-type semiconductor layer 31. Consequently, as shown in FIG. 4B, the N-type semiconductor layer 31 and the gettering site 33 respectively increase their thicknesses.

Thereafter, an N-type epitaxial layer 41 is formed by the same step as the step shown in FIG. 3D on the surface of the N-type low-resistivity semiconductor layer 31, which is the uppermost surface layer, and the substrate for semiconductor devices according to this modification is thereby completed.

In the case of the substrate for semiconductor devices according to this modification, when B is about to diffuse from the P-type semiconductor substrate 20 through the N-type low-resistivity semiconductor layer 31 into the N-type epitaxial layer 41, the gettering site 33 can capture the B. Accordingly, it is possible to prevent the N-type epitaxial layer 41 from causing a change toward the P-type due to diffusion of B contained in the P-type semiconductor substrate 20.

Further, in the case of the substrate for semiconductor devices according to this modification, the BMDs 21 formed in the P-type semiconductor substrate 20 can capture contaminant metals, such as Fe, and the gettering performance for contaminant metals can thereby be improved.

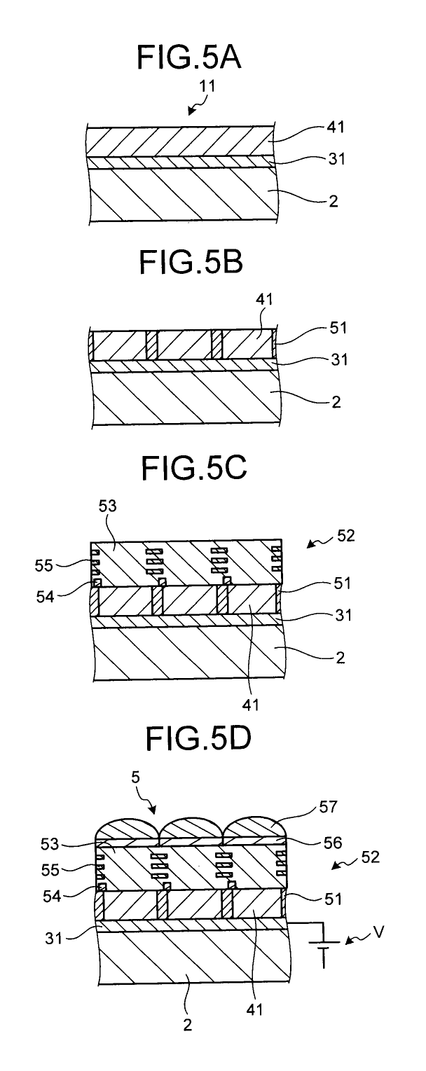

Next, with reference to FIGS. 5A to 5D, an explanation will be given of a manufacturing method of manufacturing a solid-state imaging device of a front-side irradiation type having a vertical overflow drain structure, by use of the substrate 11 for semiconductor devices according to the first embodiment. FIGS. 5A to 5D are schematic sectional views showing steps of manufacturing a solid-state imaging device of a front-side irradiation type according to the first embodiment.

As shown in FIG. 5A, at first, the substrate 11 for semiconductor devices according to the first embodiment is prepared. As described previously, the substrate 11 for semiconductor devices has a structure including the P-type semiconductor substrate 2, the N-type low-resistivity semiconductor layer 31 having a resistance value lower than that of the P-type semiconductor substrate 2, and the N-type epitaxial layer 41 having a resistance value higher than that of the N-type semiconductor layer 31, which are sequentially stacked in this order.

Subsequently, as shown in FIG. 5B, P-type element-isolation regions 51 are formed at predetermined positions in the N-type epitaxial layer 41. The P-type element-isolation regions 51 are formed to divide the N-type epitaxial layer 41 with a lattice pattern in a plan view.

Here, for example, the P-type element-isolation regions 51 are formed by ion-implanting a P-type impurity, such as B, into the N-type epitaxial layer 41 at the predetermined positions, and then performing an annealing process. Consequently, a plurality of photo diodes, which serve as a photoelectric conversion element, are formed in a two-dimensional array state, wherein the photo diodes are respectively formed by PN junctions between the N-type epitaxial layer 41 and the P-type element-isolation regions 51.

Subsequently, as shown in FIG. 5C, a multilayer wiring layer 52 is formed on the surface of the N-type epitaxial layer 41 and the P-type element-isolation regions 51. For example, the multilayer wiring layer 52 includes reading gates 54, multilayer wiring lines 55, and so forth inside an interlayer insulating film 53 made of Si oxide. Here, the reading gates 54 are the gates of respective reading transistors to which a voltage is applied when signal charges are read from the photoelectric conversion element.

Thereafter, as shown in FIG. 5D, color filters 56 and micro lenses 57 are sequentially formed on the surface of the multilayer wiring layer 52. The color filters 56 and the micro lenses 57 are disposed at positions facing respective portions of the N-type epitaxial layer 41 partitioned by the P-type element-isolation regions 51. At the end, a power supply V for applying a positive voltage is connected to the N-type low-resistivity semiconductor layer 31. Consequently, a solid-state imaging device 5 of a front-side irradiation type having a vertical overflow drain structure is manufactured.

As described above, the substrate for semiconductor devices according to the first embodiment has a structure including the P-type semiconductor substrate, the N-type low-resistivity semiconductor layer having a resistance value lower than that of the P-type semiconductor substrate, and the N-type epitaxial layer having a resistance value higher than that of the N-type semiconductor layer, which are sequentially stacked in this order.

Consequently, in the case of the substrate for semiconductor devices according to the first embodiment, it is possible to manufacture a solid-state imaging device of a front-side irradiation type having a vertical overflow drain structure, without using an N-type semiconductor substrate, which is more expensive than a P-type semiconductor substrate.

### Second Embodiment

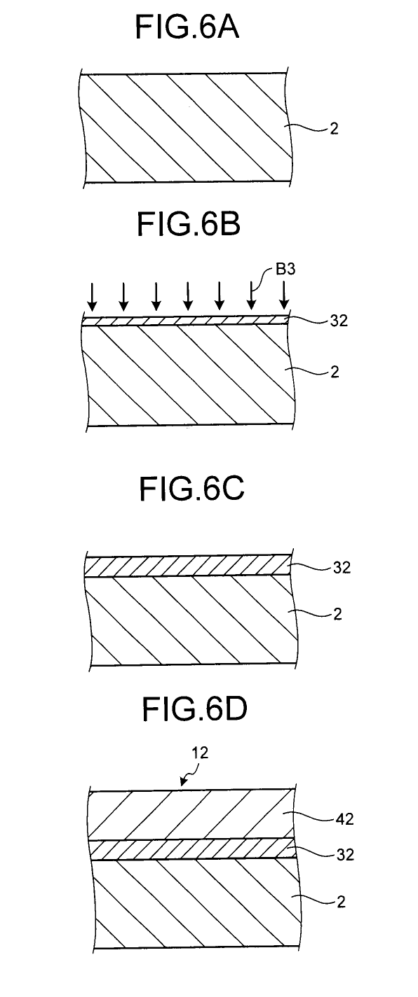

In the second embodiment, explanations will be given of the substrate 12 for semiconductor devices according to the concrete example 2 shown in FIG. 2B, in the order of a method of manufacturing the same, a modified method of manufacturing the same, and a method of manufacturing a solid-state imaging device of a rear-side irradiation type using the substrate 12 for semiconductor devices. FIGS. 6A to 6D are schematic sectional views showing steps of manufacturing the substrate 12 for semiconductor devices according to the second embodiment.

When the substrate 12 for semiconductor devices is manufactured, as shown in FIG. 6A, a P-type semiconductor substrate 2 is prepared. The P-type semiconductor substrate 2 is a semiconductor substrate 2 prepared such that a DZ (defect-free layer) is formed at a surface layer and an IG (intrinsic gettering) layer is formed inside the semiconductor substrate 2, as used in the first embodiment.

Subsequently, as shown in FIG. 6B, the surface of the P-type semiconductor substrate 2 is irradiated with an ion beam B3 containing P-type impurity ions, such as B, so that B ions are ion-implanted into a surface layer of the P-type semiconductor substrate 2, and a P-type low-resistivity semiconductor layer 32 is thereby formed.

Here, the B dose amount is set to be 5E14/cm² to 3E15/cm². Thereafter, an annealing process is performed to activate B ions in the P-type low-resistivity semiconductor layer 32. Consequently, as shown in FIG. 6C, the P-type low-resistivity semiconductor layer 32 increases its thickness, and comes to have a B concentration of 4.0E18/cm³ or more and a resistance value of about 0.01 Ωcm to 0.02 Ωcm. Here, the thickness of the P-type low-resistivity semiconductor layer 32 is set such that the thickness of a region of 7E17/cm² or more is 3 um or more.

Subsequently, as shown in FIG. 6D, a P-type epitaxial layer 42 is formed on the surface of the P-type low-resistivity semiconductor layer 32, and the substrate 12 for semiconductor devices is thereby completed. For example, the P-type epitaxial layer 42 is formed by epitaxial growth of a Si layer doped with a P-type impurity, such as B, which is performed by use of, e.g., CVD, on the surface of the P-type low-resistivity semiconductor layer 32. The P-type epitaxial layer 42 is formed to have a desired B concentration within a range of 1E15/cm³ to 2E16/cm³ in accordance with the pixel design.

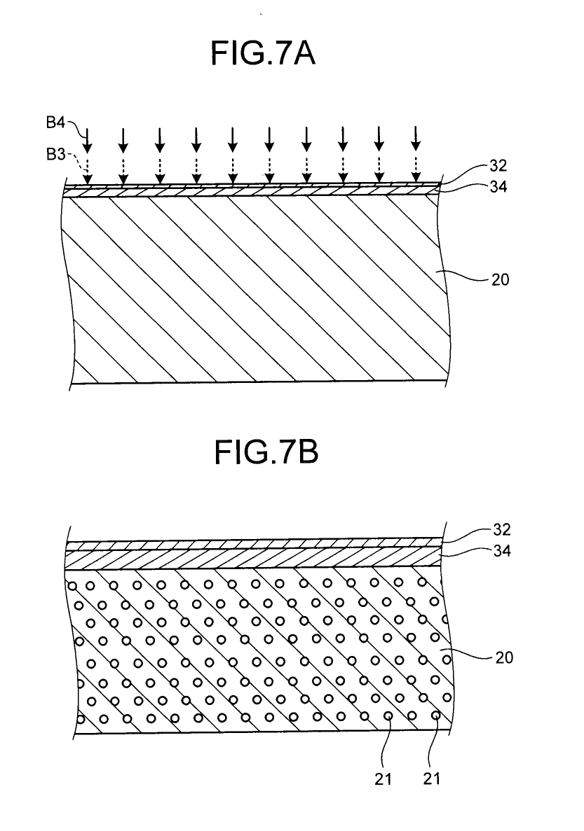

Next, with reference to FIGS. 7A and 7B, an explanation will be given of a modified method of manufacturing the substrate 12 for semiconductor devices. FIGS. 7A and 7B are schematic sectional views showing steps of manufacturing a substrate for semiconductor devices according to a modification of the second embodiment.

As shown in FIG. 7A, in this modified manufacturing method, a P-type semiconductor substrate 20 containing oxygen at a predetermined concentration is prepared. For example, the oxygen concentration in the P-type semiconductor substrate 20 is set to be 12E17/cm³ to 18E17/cm³.

Then, the surface of the P-type semiconductor substrate 20 is sequentially irradiated with an ion beam B3 containing, e.g., C (carbon), and an ion beam B4 containing P-type impurity ions, such as B.

Here, the C dose amount is set to be 1.0E15/cm² to 2.0E16/cm², and the B dose amount is set to be 1.0E14/cm² to 3.0E15/cm². Consequently, a gettering site 34 containing ion-implanted C and a P-type low-resistivity semiconductor layer 32 containing ion-implanted B are provided in a sequentially stacked state at a surface layer of the P-type semiconductor substrate 20.

Thereafter, an annealing process is performed to activate B ions in the P-type low-resistivity semiconductor layer 32. Here, for example, an annealing process is performed at 780° C. for 3 hours, and then another annealing process is further performed at 100° C. for 16 hours.

Consequently, as shown in FIG. 7B, the P-type low-resistivity semiconductor layer 32 and the gettering site 34 come to have a total thickness of 3 μm or more.

Further, at this time, due to the annealing process, oxygen contained in the P-type semiconductor substrate 20 is precipitated, and BMDs 21 are thereby formed. Thereafter, an P-type epitaxial layer 42 is formed by the same step as the step shown in FIG. 6D on the surface of the P-type low-resistivity semiconductor layer 32, which is the uppermost surface layer, and the substrate for semiconductor devices according to this modification is thereby completed.

In the case of the substrate for semiconductor devices according to this modification, the gettering site 34 is sandwiched between the P-type semiconductor substrate 20 and the P-type low-resistivity semiconductor layer 32, and the distance between the P-type semiconductor substrate 20 and the P-type epitaxial layer 42 can thereby be increased. Accordingly, it is possible to easily control the grinding amount in grinding the P-type semiconductor substrate 20 in the steps of manufacturing a solid-state imaging device of a rear-side irradiation type, as described later.

Further, in the case of the substrate for semiconductor devices according to this modification, the BMDs 21 formed in the P-type semiconductor substrate 20 can capture contaminant metals, such as Fe, and the gettering performance for contaminant metals can thereby be improved.

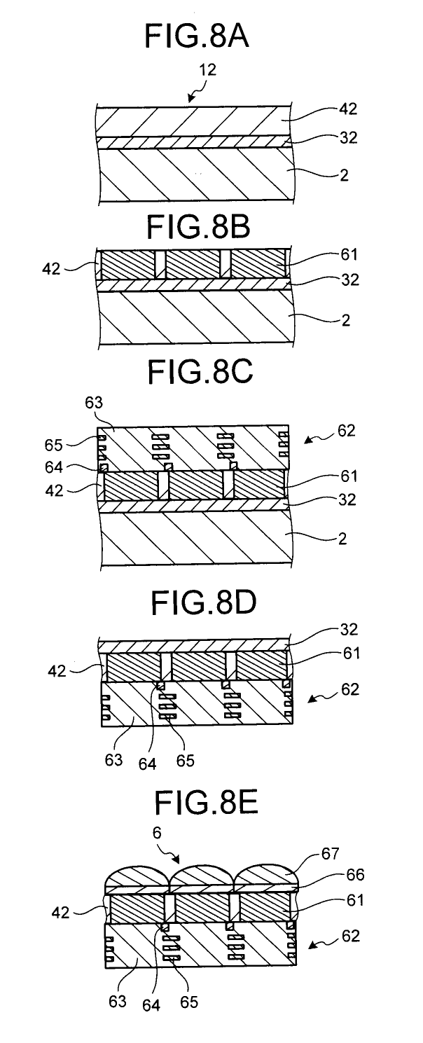

Next, with reference to FIGS. 8A to 8D, an explanation will be given of a manufacturing method of manufacturing a solid-state imaging device of a rear-side irradiation type, by use of the substrate 12 for semiconductor devices according to the second embodiment. FIGS. 8A to 8E are schematic sectional views showing steps of manufacturing a solid-state imaging device of a rear-side irradiation type according to the second embodiment.

As shown in FIG. 8A, at first, the substrate 12 for semiconductor devices according to the second embodiment is prepared. As described previously, the substrate 12 for semiconductor devices has a structure including the P-type semiconductor substrate 2, the P-type low-resistivity semiconductor layer 32 having a resistance value lower than that of the P-type semiconductor substrate 2, and the P-type epitaxial layer 42 having a resistance value higher than that of the P-type low-resistivity semiconductor layer 32, which are sequentially stacked in this order.

Subsequently, as shown in FIG. 8B, N-type charge accumulation regions 61 are formed at predetermined positions in the P-type epitaxial layer 42, in a two-dimensional array state. Consequently, the N-type charge accumulation regions 61 are electrically isolated form each other by respective portions of the P-type epitaxial layer 42.

Here, for example, the N-type charge accumulation regions 61 are formed by ion-implanting an N-type impurity, such as P, into the P-type epitaxial layer 42 at the predetermined positions, and then performing an annealing process. Consequently, a plurality of photo diodes, which serve as a photoelectric conversion element, are formed in a two-dimensional array state, wherein the photo diodes are respectively formed by PN junctions between the P-type epitaxial layer 42 and the N-type charge accumulation regions 61.

Subsequently, as shown in FIG. 8C, a multilayer wiring layer 62 is formed on the surface of the P-type epitaxial layer 42 and the N-type charge accumulation regions 61. For example, the multilayer wiring layer 62 includes reading gates 64, multilayer wiring lines 65, and so forth inside an interlayer insulating film 63 made of Si oxide. Here, the reading gates 64 are the gates of respective reading transistors to which a voltage is applied when signal charges are read from the photoelectric conversion element.

Thereafter, as shown in FIG. 8D, the structure body shown in FIG. 8C is reversed upside down, and grinding and polishing are performed to the P-type semiconductor substrate 2 from the rear side (the upper side in this state) by use of, e.g., BSG (Back Side Grinding) and CMP (Chemical Mechanical Polishing), so that the central portion of the P-type low-resistivity semiconductor layer 32 is exposed.

At this time, as described previously, the P-type low-resistivity semiconductor layer 32 has a thickness of 3 μm or more, and, thus, when the grinding and polishing are performed to the P-type semiconductor substrate 2, the grinding and polishing can be stopped near the center of the P-type low-resistivity semiconductor layer 32 in the thickness direction.

Thereafter, the P-type low-resistivity semiconductor layer 32 is removed by selective wet etching. In this case, the difference between the B concentration in the P-type low-resistivity semiconductor layer 32 and the B concentration in the P-type epitaxial layer 42 is utilized to perform the wet etching to selectively remove the P-type low-resistivity semiconductor layer 32. Consequently, the rear side (the upper side in this state) of the P-type epitaxial layer 42 and the N-type charge accumulation regions 61 is exposed.

At the end, as shown in FIG. 8E, color filters 66 and micro lenses 67 are sequentially formed on the rear side (the upper side in this state) of the P-type epitaxial layer 42 and the N-type charge accumulation regions 61. The color filters 66 and the micro lenses 67 are disposed at positions facing the respective N-type charge accumulation regions 61. Consequently, a solid-state imaging device 6 of a rear-side irradiation type is manufactured.

As described above, the substrate for semiconductor devices according to the second embodiment has a structure including the P-type semiconductor substrate, the P-type semiconductor layer having a resistance value lower than that of the P-type semiconductor substrate, and the P-type epitaxial layer having a resistance value higher than that of the P-type semiconductor layer, which are sequentially stacked in this order. Consequently, in the case of the substrate for semiconductor devices according to the second embodiment, it is possible to easily control the grinding amount in grinding the P-type semiconductor substrate in the steps of manufacturing a solid-state imaging device of a rear-side irradiation type.

### Third Embodiment

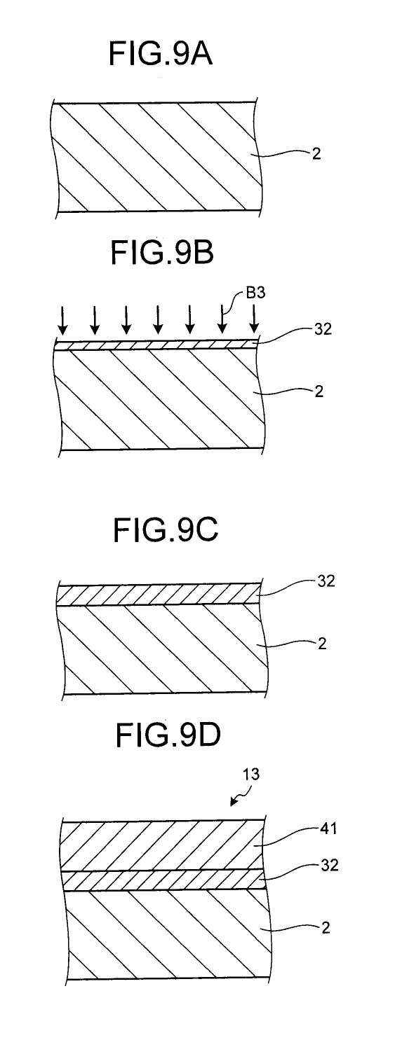

In the third embodiment, an explanation will be given of a method of manufacturing the substrate 13 for semiconductor devices according to the concrete example 3 shown in FIG. 2C. FIGS. 9A to 9D are schematic sectional views showing steps of manufacturing the substrate 13 for semiconductor devices according to the third embodiment.

When the substrate 13 for semiconductor devices is manufactured, as shown in FIG. 9A, a P-type semiconductor substrate 2 is prepared. The P-type semiconductor substrate 2 is a semiconductor substrate 2 prepared such that a DZ (defect-free layer) is formed at a surface layer and an IG (intrinsic gettering) layer is formed inside the semiconductor substrate 2, as used in the first and second embodiments.

Subsequently, as shown in FIG. 9B, the surface of the P-type semiconductor substrate 2 is irradiated with an ion beam B3 containing P-type impurity ions, such as B, so that B ions are ion-implanted into a surface layer of the P-type semiconductor substrate 2, and a P-type low-resistivity semiconductor layer 32 is thereby formed.

Here, the B dose amount is set to be 1E14cm² to 3E15/cm². Thereafter, an annealing process is performed to activate B ions in the P-type low-resistivity semiconductor layer 32. Consequently, as shown in FIG. 9C, the P-type low-resistivity semiconductor layer 32 increases its thickness, and comes to have a B concentration of 4.0E18/cm³ or more and a resistance value of about 0.01 Ωcm to 0.02 Ωcm at the central portion.

Subsequently, as shown in FIG. 9D, an N-type epitaxial layer 41 is formed on the surface of the P-type low-resistivity semiconductor layer 32, and the substrate 13 for semiconductor devices is thereby completed. For example, the N-type epitaxial layer 41 is formed by epitaxial growth of a Si layer doped with an N-type impurity, such as P, on the surface of the P-type low-resistivity semiconductor layer 32. The N-type epitaxial layer 41 is formed to have a desired P concentration within a range of 1E14/cm³ to 2E15/cm³.

As described above, the substrate for semiconductor devices according to the third embodiment has a structure including the P-type semiconductor substrate, the P-type semiconductor layer having a resistance value lower than that of the P-type semiconductor substrate, and the N-type epitaxial layer having a resistance value higher than that of the P-type semiconductor layer, which are sequentially stacked in this order.

In the case of the substrate for semiconductor devices according to the third embodiment, when a photoelectric conversion element is formed in the N-type epitaxial layer, a certain thickness of the photoelectric conversion element can be obtained. Further, the P-type semiconductor layer can be grounded such that it serves as ground.

Further, according to the first to third embodiments described above, an alteration and/or a condition change of a substrate for semiconductor devices can be performed in a desired way in a step after formation of the epitaxial layer. Accordingly, it is possible to shorten the delivery period for a prototype of a substrate with a new specification, and to shorten the development schedule for a solid-state imaging device with a new specification.

In the first to third embodiments described above, the P-type or N-type semiconductor layer is formed by ion-implanting an impurity into a surface layer of the P-type semiconductor substrate and then performing an annealing process. However, the P-type or N-type semiconductor layer may be formed by epitaxial growth, for example.

Further, a substrate for semiconductor devices according to an embodiment is not limited to the structures according to the first to third embodiments. For example, a substrate for semiconductor devices according to an embodiment may have a structure including a P-type semiconductor substrate, an N-type low-resistivity semiconductor layer provided at a surface layer of the P-type semiconductor substrate and having a resistance value lower than that of the P-type semiconductor substrate, and a P-type epitaxial layer provided on the surface of the N-type low-resistivity semiconductor layer and having a resistance value higher than that of the N-type low-resistivity semiconductor layer.

According to each of the substrates for semiconductor devices described above, for example, a semiconductor device that has been manufactured by use of an N-type semiconductor substrate so far can be manufactured by use of a P-type semiconductor substrate, which is less expensive than the N-type semiconductor substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate for semiconductor devices, comprising:
a P-type semiconductor substrate;
a P-type or N-type semiconductor layer provided at a surface layer of the semiconductor substrate and having a resistance value lower than a resistance value of the semiconductor substrate; and
a P-type or N-type epitaxial layer provided on a surface of the semiconductor layer and having a resistance value higher than the resistance value of the semiconductor layer.

2. The substrate for semiconductor devices according to claim 1, wherein the semiconductor substrate includes a gettering layer below the semiconductor layer.

3. The substrate for semiconductor devices according to claim 1, wherein the semiconductor substrate includes a layer containing carbon below the semiconductor layer.

4. The substrate for semiconductor devices according to claim 1, wherein the semiconductor substrate includes a DZ (Denuded Zone) layer at a surface layer.

5. The substrate for semiconductor devices according to claim 1, wherein the semiconductor substrate includes BMDs (Bulk Micro Defect).

6. A method of manufacturing a substrate for semiconductor devices, the method comprising:
forming a P-type or N-type semiconductor layer at a surface layer of a semiconductor substrate, the semiconductor layer having a resistance value lower than a resistance value of the semiconductor substrate; and
forming a P-type or N-type epitaxial layer on a surface of the semiconductor layer, the epitaxial layer having a resistance value higher than the resistance value of the semiconductor layer.

7. The method of manufacturing a substrate for semiconductor devices according to claim 6, wherein forming the semiconductor layer includes ion-implanting P-type or N-type impurity ions into the semiconductor substrate.

8. The method of manufacturing a substrate for semiconductor devices according to claim 6, wherein the method comprises forming a gettering layer in the semiconductor substrate below the semiconductor layer.

9. The method of manufacturing a substrate for semiconductor devices according to claim 8, wherein forming the gettering layer includes ion-implanting carbon into the semiconductor layer.

10. The method of manufacturing a substrate for semiconductor devices according to claim 6, wherein the method comprises forming a DZ (Denuded Zone) layer at a surface layer of the semiconductor layer by performing an annealing process to the semiconductor substrate.

11. The method of manufacturing a substrate for semiconductor devices according to claim 6, wherein the method comprises forming BMDs (Bulk Micro Defect) inside the semiconductor substrate.

12. The method of manufacturing a substrate for semiconductor devices according to claim 8, wherein forming the gettering layer is performed before forming the semiconductor layer.

13. A solid-state imaging device comprising:
a P-type semiconductor substrate;
a P-type or N-type semiconductor layer provided at a surface layer of the semiconductor substrate and having a resistance value lower than a resistance value of the semiconductor substrate;
an N-type epitaxial layer provided on a surface of the semiconductor layer and having a resistance value higher than the resistance value of the semiconductor layer; and
a photoelectric conversion element provided in the epitaxial layer.

14. The solid-state imaging device according to claim 13, wherein the semiconductor substrate includes a gettering layer below the semiconductor layer.

15. The solid-state imaging device according to claim 13, wherein the semiconductor substrate includes a layer containing carbon below the semiconductor layer.

16. The solid-state imaging device according to claim 13, wherein the semiconductor substrate includes a DZ (Denuded Zone) layer at a surface layer.

17. The solid-state imaging device according to claim 13, wherein the semiconductor substrate includes BMDs (Bulk Micro Defect).

18. The solid-state imaging device according to claim 13, wherein the semiconductor layer is of an N-type, the solid-state imaging device is of a front-side irradiation type, and the semiconductor layer has an overflow drain structure that is grounded.

19. The solid-state imaging device according to claim 13, wherein the semiconductor layer is of a P-type, the solid-state imaging device is of a front-side irradiation type, and the semiconductor layer is grounded.
